(19) United States
(12) Patent Application Publication
(10) Pub. No.: US 2009/0224226 A1
(43) Pub. Date: Sep. 10, 2009

(54) LIGHT EMITTING DEVICE OF GROUP III NITRIDE BASED SEMICONDUCTOR

(75) Inventors: SHIH CHENG HUANG, HSINCHU CITY (TW); SHUN KUEI YANG, KAOHSIUNG COUNTY (TW); CHIA HUNG HUANG, TAICHUNG CITY (TW); CHIH PENG HSU, TAINAN COUNTY (TW); SHIH HSIUNG CHAN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/397,507

(22) Filed: Mar. 4, 2009

(30) Foreign Application Priority Data
Mar. 5, 2008 (TW) 097107610

(51) Int. Cl. H01L 29/06

(52) U.S. Cl. 257/13; 257/E29.069

(57) ABSTRACT

A light emitting device of Group III nitride based semiconductor comprises a substrate, an N-type semiconductor layer formed on the substrate, an active layer formed on the N-type semiconductor layer, and a P-type semiconductor layer formed on the quantum well layer. The active layer comprises at least one quantum well layer, at least two barrier layers formed to sandwich the quantum well layer therebetween and at least one stress relieving layer, wherein the stress relieving layer is interposed between the quantum well layer and one of the at least two barrier layers, and the composition of the stress relieving layer, made of Group III nitride based material, is graded along the direction from the quantum well layer to the barrier layers adjacent thereto.

### BACKGROUND OF THE INVENTION

1. Field of the Invention

The present invention relates to a light emitting device of Group III nitride based semiconductor, and relates more particularly to a light emitting device of Group III nitride based semiconductor, the active layer of which has increased lumen output and high optical efficiency.

2. Description of the Related Art

With wide application of light emitting diode (LED) devices in different products, semiconductor materials used for fabricating blue light LEDs are becoming the focus of much research in the optoelectronic industry. At present, semiconductor materials such as zinc selenide (ZnSe), silicon carbide (SiC), and indium gallium nitride (InGaN) are preferred for blue light LEDs, and these semiconductor materials have wide band gaps of above 2.6 eV. Because gallium nitride is a direct gap semiconductor, it can have high luminous flux, and compared to zinc selenide, which is also a direct gap semiconductor, the GaN LED can last longer.

FIG. 1A shows a light-emitting apparatus, disclosed in U.S. Pat. No. 7,067,838. FIG. 1B is an illustrative diagram of the magnitudes of band gaps of the light-emitting apparatus of FIG. 1A. The light-emitting apparatus 10 comprises a sapphire substrate 11, a buffer layer 19, an N-type contact layer 12, an N-type cladding layer 13, an active layer 15, a P-type block layer 16, a P-type cladding layer 17 and a P-type contact layer 18, wherein the active layer 15 comprises an N-type first barrier layer 153, a plurality of N-type InGaN well layers 151, and a plurality of N-type second barrier layers 152. More specifically, when the band gap energy of the P-type block layer 16 is Egb, the band gap energy of the N-type second barrier layer 152 is Eg2, the band gap energy of the N-type first barrier layer 153 is Eg 1, and the band gap energy of the N-type cladding layer 13 and the P-type cladding layer 17 is Egc, the relationship Egb>Eg2>Eg1>Egc must be satisfied, as shown in FIG. 1B. Due to the confinement of carriers from a P-type semiconductor layer by the P-type block layer 16 and the confinement of carriers from an N-type semiconductor layer by the N-type first barrier layer 153, the electrons and carriers are confined in the active layer 15 and the recombination of electrons and holes in the active layer 15 can be facilitated. However, the structure is complex, and increases the difficulty of mass production.

FIG. 2A is a schematic diagram of an active region of a light emitting diode, disclosed in U.S. Pat. No. 6,955,933. FIG. 2B is a simulated band structure for the light emitting diode of FIG. 2A. The active region 20 comprises quantum well layers (12, 23, and 25) and barrier layers (22, 24, and 26). The quantum well layers (12, 23, and 25) and the barrier layers (22, 24, and 26) are formed from a III-Nitride semiconductor alloy of AlₓIn_{y}Ga_{1-x-y}N where 0≦x<1, 0≦y<1, x+y≦1. Specifically, the compositions of the quantum well layers (12, 23, and 25) and the barrier layers (22, 24, and 26) are graded (gradually increasing or gradually decreasing) in a direction substantially perpendicular to the surface of the N-type semiconductor layer of the light emitting diode. Due to the gradation of the composition of the layers, each layer has a graded band gap, as shown in FIG. 2B. However, this type of the structure will lower the total energy of the band gap of the active region 20 and results in variations of wavelength emitted.

FIG. 3 is a band structure for an active layer, disclosed in U.S. Pat. No. 6,936,838. The active layer comprises an N-type semiconductor layer 31, a barrier layer 32, a quantum well layer 33, and a P-type semiconductor layer 34. The barrier layer 32 comprises an internal layer portion doped with N-type impurities 321 and an anti-diffusion film 332. Specifically, the band gap of the barrier layer 32 is greater than that of the quantum well layer 33. The anti-diffusion film 332 prevents N-type impurities from being diffused into the quantum well layer 33, so that it may achieve an improvement in optical power of the quantum well layer 33. The band structure for the active layer is similar to conventional multiple quantum well structures, but an anti-diffusion film 332 is added between the barrier layer 32 and the quantum well layer 33.

FIG. 4 is a band structure for an active layer, disclosed in U.S. Pat. No. 7,106,090. The active layer comprises at least one quantum well layer 42 and two barrier layers 41 and 43 sandwiching the quantum well layer 42. The quantum well layer 42 having a step-like energy band gap profile includes four single layers 421-424. The indium content gradually increases step by step from one layer to the next layer 421, 422, 423, 424, and finally the last single layer 424 has the highest indium content. Compared to conventional quantum well layer with uniform energy band gap profile, the quantum well layer with a step-like energy band gap profile or with graded energy band gap profile will reduce the total band gap energy so as to change the wavelength and other characteristics of emitting light. (See FIG. 4 of U.S. Pat. No. 7,106,090.)

Therefore, a light emitting diode with none of the above-mentioned issues that can guarantee the quality and increase the power of the emitting light from the active layer thereof is required by the market.

### SUMMARY OF THE INVENTION

The primary aspect of the present invention is to provide a light emitting device of Group III nitride based semiconductor, which includes a stress relieving layer disposed between the quantum well layer and the barrier layer such that the lattice mismatch stress in the active layer can be relieved, and the optical efficiency can be increased.

In view of the above aspect, the present invention proposes a light emitting device of Group III nitride based semiconductor, which comprises a substrate, an N-type semiconductor layer formed on the substrate, an active layer formed on the N-type semiconductor layer, and a P-type semiconductor layer formed on the quantum well layer. The active layer comprises at least one quantum well layer, at least two barrier layers formed to sandwich the quantum well layer therebetween and at least one stress relieving layer, wherein the stress relieving layer is interposed between the quantum well layer and one of the at least two barrier layers, and the composition of the stress relieving layer, made of Group III nitride based material, is a graded distribution along the direction from the quantum well layer to the barrier layers adjacent thereto.

According to one embodiment, the Group III nitride based material of the stress relieving layer is represented by the formula AlₓIn_{y}Ga_{1-x-y}N, wherein 0≦x<1, 0≦y<1 and x+y≦1, wherein the composition ratio among components, Al (aluminum), Ga (gallium), and In (indium), is graded along the direction from the quantum well layer to the barrier layers adjacent thereto.

According to one embodiment, the grading distribution is monotonic increase, which can be linearly graded or non-linearly curvature graded.

According to one embodiment, the grading distribution is equally stepwise graded or is unequally stepwise graded.

According to one embodiment, the stress relieving layer comprises a multiple layer structure, and each layer is made of a Group III nitride based material with different composition ratio. The stress relieving layer is a Group III nitride based semiconductor layer doped with N-type impurities or is an undoped Group III nitride based semiconductor layer.

According to one embodiment, the light emitting device of Group III nitride based semiconductor further comprises a buffer layer disposed between the substrate and the N-type semiconductor layer, and also further comprises a current block layer disposed between the active layer and the P-type semiconductor layer.

According to one embodiment, the active layer includes a single quantum well layer or multiple quantum well layers.

According to another embodiment, the present invention proposes a light emitting device of Group III nitride based semiconductor, which comprises a substrate, an N-type semiconductor layer formed on the substrate, an active layer, and a P-type semiconductor layer. The active layer comprises at least one quantum well layer, at least two barrier layers formed to sandwich the quantum well layer, and at least two stress relieving layers, wherein stress relieving layers are separately interposed between the quantum well layer and the at least two barrier layers, and each stress relieving layer has a greater band gap energy than that of the quantum well layer and has a smaller band gap energy than that of the barrier layer adjacent thereto. Each stress relieving layer has a graded band gap along the direction from the quantum well layer to the barrier layers adjacent thereto.

### BRIEF DESCRIPTION OF THE DRAWINGS

The invention will be described according to the appended drawings in which:

FIG. 1A shows a light-emitting apparatus, disclosed in U.S. Pat. No. 7,067,838;

FIG. 1B is an illustrative diagram of the magnitudes of band gaps of the light-emitting apparatus of FIG. 1A;

FIG. 2A is a schematic diagram of an active region of a light emitting diode, disclosed in U.S. Pat. No. 6,955,933;

FIG. 2B is a simulated band structure for the light emitting diode of FIG. 2A;

FIG. 3 is a band structure for an active layer, disclosed in U.S. Pat. No. 6,936,838;

FIG. 4 is a band structure for an active layer, disclosed in U.S. Pat. No. 7,106,090;

FIG. 5 is a schematic diagram of a light emitting diode device of Group III nitride based semiconductor according to the first embodiment of the present invention;

FIG. 6A is an illustrative diagram of the magnitudes of band gaps of the active layer with a single quantum well layer according to one embodiment of the present invention;

FIG. 6B is an illustrative diagram of a prior art active layer with a single quantum well layer;

FIG. 7A is an illustrative diagram of the magnitudes of band gaps of the active layer with a single quantum well layer according to another embodiment of the present invention;

FIG. 7B is an illustrative diagram of a prior art active layer with a single quantum well layer;

FIGS. 8 to 11 are illustrative diagrams of the magnitudes of band gaps of the active layers each having a single quantum well layer according to other embodiments of the present invention;

FIG. 12 is a schematic diagram of a light emitting device of Group III nitride based semiconductor according to the second embodiment of the present invention;

FIG. 13A and FIG. 13B are illustrative diagrams of the magnitudes of band gaps of the active layer with multiple quantum well layers according to another embodiment of the present invention;

FIG. 14 shows a comparison graph of the output intensities of a light emitting device of Group III nitride based semiconductor according to one embodiment of the present invention and of a prior art device; and

FIG. 15 is a schematic diagram of a light emitting device of Group III nitride based semiconductor according to the third embodiment of the present invention.

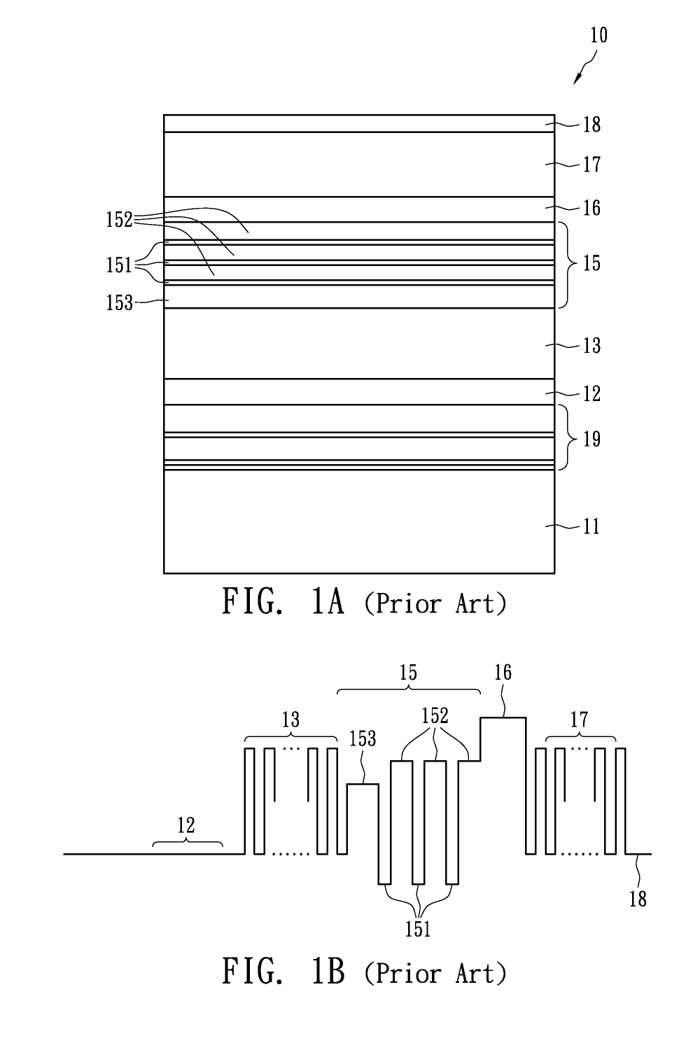

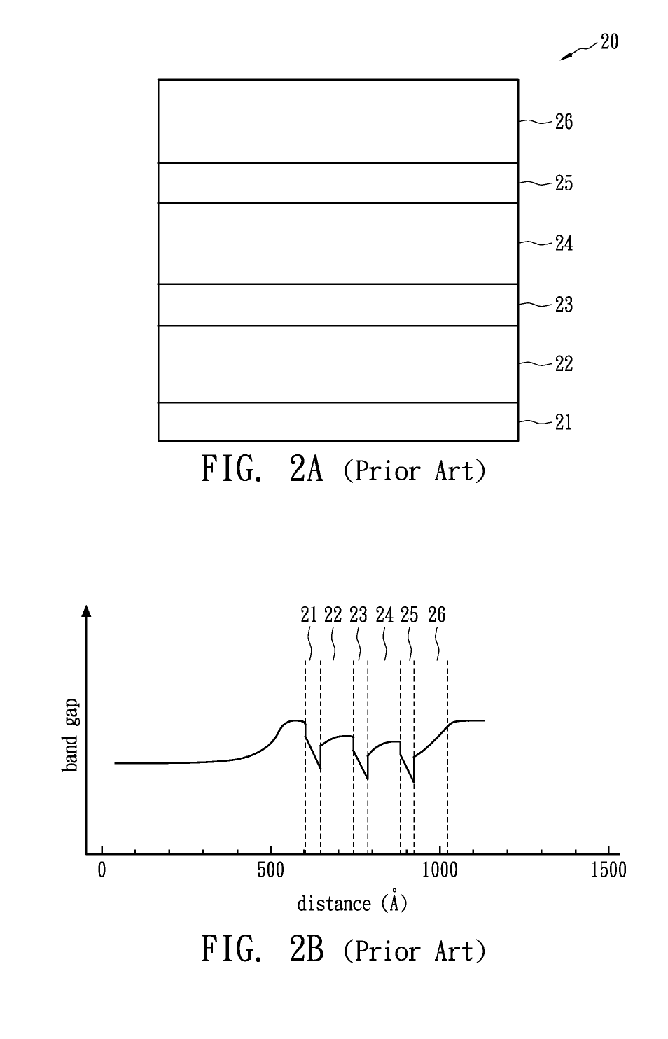

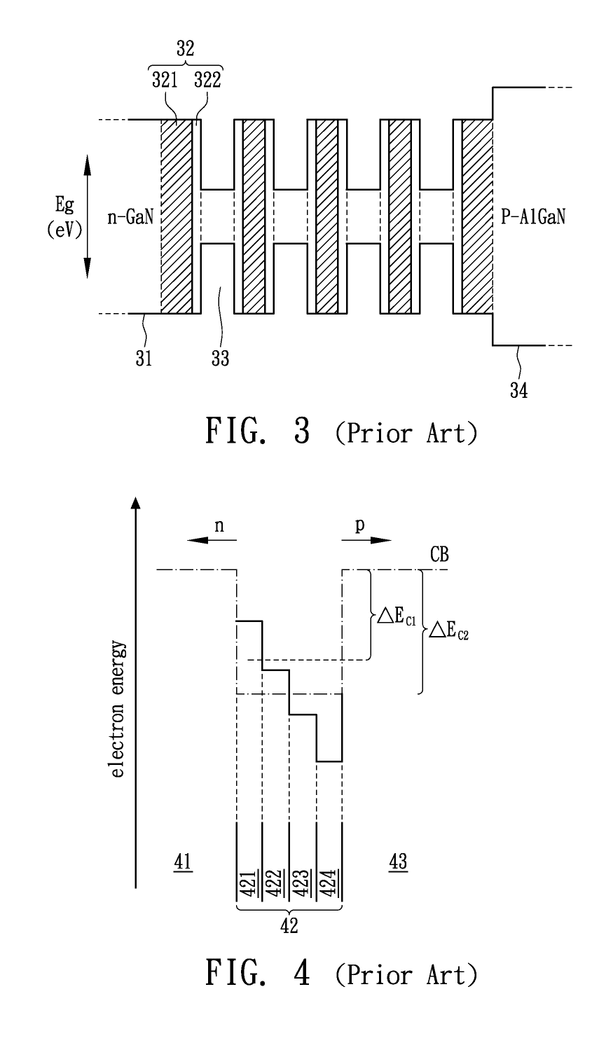

### DETAILED DESCRIPTION OF THE INVENTION

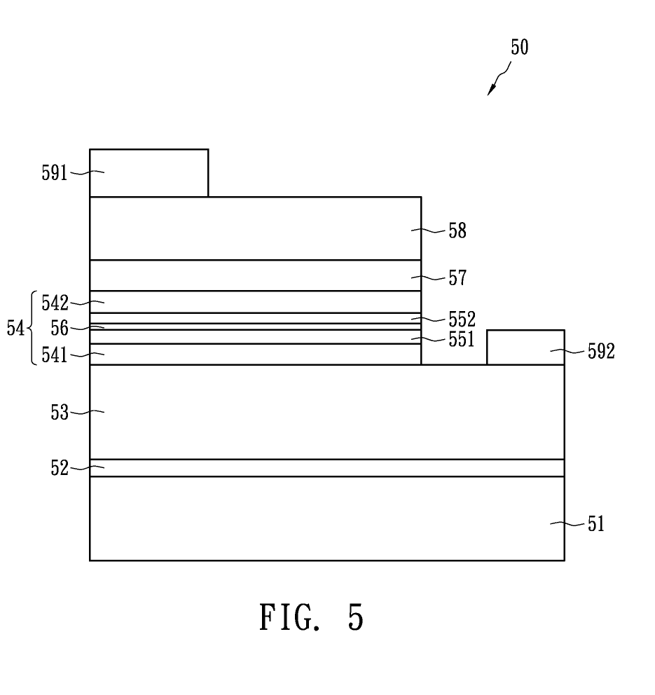

FIG. 5 is a schematic diagram of a light emitting diode device of Group III nitride based semiconductor according to the first embodiment of the present invention. The light emitting diode device of Group III nitride based semiconductor 50 comprises a substrate 51, a buffer layer 52, an N-type semiconductor layer 53, an active layer 54, a current block layer 57 and a P-type semiconductor layer 58. The active layer 54 comprises at least one quantum well layer 56, a first barrier layer 541 and a second barrier layer 542. The first barrier layer 541 and the second barrier layer 542 are formed to sandwich the quantum well layer 56 therebetween. In addition, the active layer 54 further comprises a first stress relieving layer 551 and a second stress relieving layer 552. The first stress relieving layer 551 is disposed between the first barrier layer 541 and the quantum well layer 56, and the second stress relieving layer 552 is disposed between the second barrier layer 542 and the quantum well layer 56. The N-type semiconductor layer 53 further comprises an N-type electrode layer 592, and the P-type semiconductor layer 58 further comprises a P-type electrode layer 591.

The stress relieving layers 551 and 552 are made of Group III nitride based material, and the compositions of the stress relieving layers 551 and 552 are graded along the direction from the quantum well layer 56 to the barrier layers 541 or 542 adjacent to the quantum well layer 56. The stress relieving layer 551 or 552 can be a Group III nitride based semiconductor layer doped with N-type impurities or can be an undoped Group III nitride based semiconductor layer. The Group III nitride based semiconductor material can be, for example, a material represented by the formula AlₓIn_{y}Ga_{1-x-y}N, wherein 0≦x<1, 0≦y<1 and x+y≦1, and the composition ratio among components, Al (aluminum), Ga (gallium), and In (indium), is graded in a thickness-wise direction. Alternatively, the thickness of the stress relieving layer 551 or 552 is greater than the thickness of the quantum well layer 56, but less than the thickness of the barrier layer 541 or 542. Moreover, the stress relieving layer 551 or 552 may comprise a multiple layer structure, and each layer is made of a Group III nitride based material with different composition ratio.

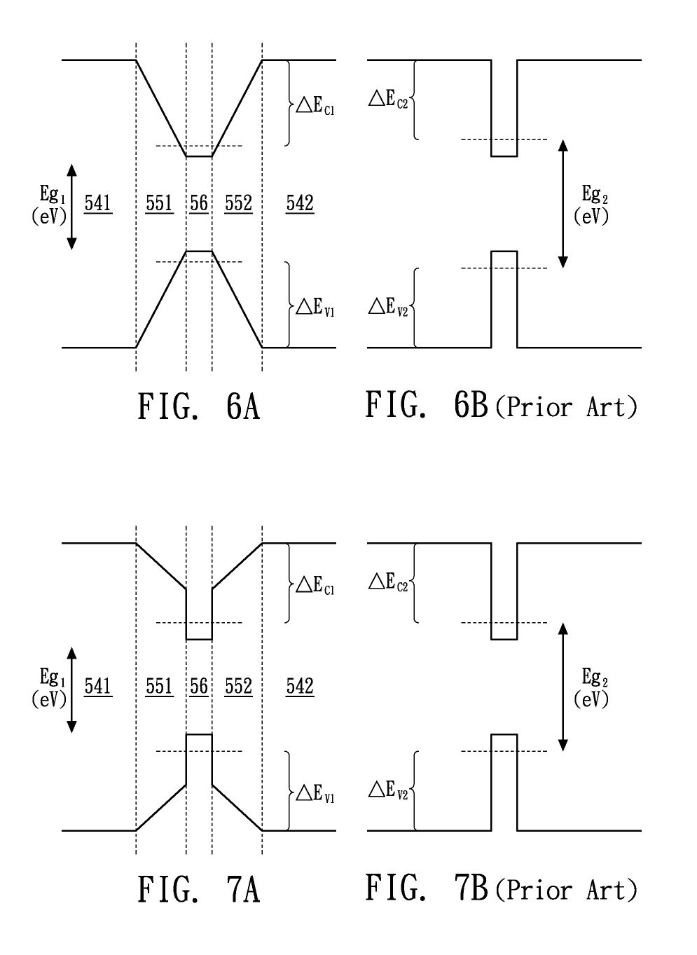

FIG. 6A is an illustrative diagram of the magnitudes of band gaps of the active layer with a single quantum well layer according to one embodiment of the present invention. Referring to FIG. 6A, the upper is the conduction band variation profile, Ec, of the active layer 54, and the lower is the valence band variation profile, Ev, of the active layer 54, the energy difference between the Ec and the Ev is the band gap energy, Eg. The band gap energy of the stress relieving layer 551 is greater than that of the quantum well layer 56, and the band gap of the stress relieving layer 551 is smaller than that of the adjacent first barrier layer 541. The stress relieving layer 551 has a graded band gap along the direction from the quantum well layer 56 to the first barrier layer 541. In the present invention, the first stress relieving layer 551 has a monotonically linearly increasing band gap toward the first barrier layer 541.

The active layer 54 has band gap energy, Eg1, which is equal to the sum of the conduction band difference ΔEc1 and valence band difference ΔEv1, and namely, Eg1=ΔEc1+ΔEv1. As shown in FIG. 6B, compared to prior art active layers, it can be found that ΔEc1>ΔEc2 and ΔEv1>ΔEv2. Therefore, the active layer 54 of the present invention has a greater conduction band difference than a prior art active layer, and namely, Eg1<Eg2, and consequently, the active layer 54 can emit light of longer wavelength, which is something the above-mentioned prior art active layers cannot achieve.

FIG. 7A is an illustrative diagram of the magnitudes of band gaps of the active layer with a single quantum well layer according to another embodiment of the present invention. The first stress relieving layer 551 has a monotonically linearly increasing band gap toward the first barrier layer 541; however, the band gap becomes discontinuous and smaller at the interface between the quantum well layer 56 and the adjacent stress relieving layer 551. As shown in FIG. 7B, compared to prior art active layers, it can be found that ΔEc1=ΔEc2 and ΔEv1=ΔEv2. Thus, the band gap energy of the active layer 54 of the present invention is equal to the band gap energy of prior art active layers, namely, Eg1=Eg2, and consequently, the active layer 54 can emit light having the same wavelength, and prior art active layers can only emit light of shorter wavelength.

In consideration of the possibility of the non-linear growth of an epitaxial film, the stress relieving layer 551 shown in FIG. 7A has a monotonically increasing band gap toward the first barrier layer 541 such that the active layer 551 in FIG. 7A can have similar light emitting characteristics to the active layer 551 of FIG. 6A.

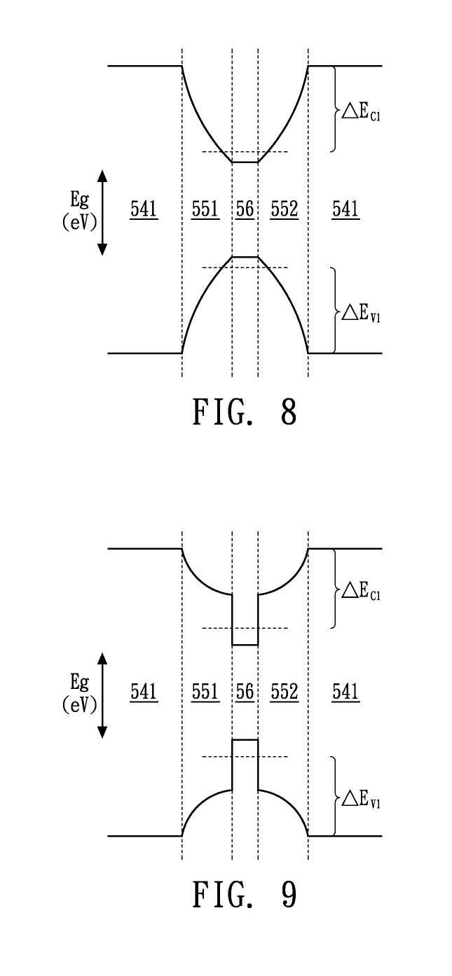

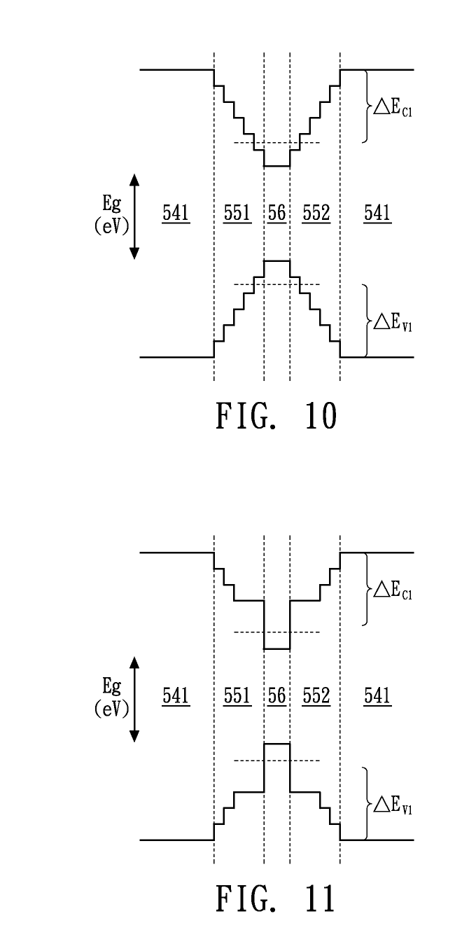

Compared to FIG. 7A, the band gap profiles of the first stress relieving layer 551 and the second stress relieving layer 552 in the embodiments of FIG. 8 and FIG. 9 are non-linear profiles different from the linear profile shown in FIG. 7A; however, the active layer 54 having a non-linear profile can have the similar light emitting characteristics to the active layer 54 having the profile shown in FIG. 7A.

Compared to FIG. 6A, the band gap profiles of the first stress relieving layer 551 and the second stress relieving layer 552 in FIG. 10 are stepwise increasing, which are different from the monotonic increasing band gap shown in the above-mentioned embodiments. However, the active layer 54 having an increasing stepwise profile can have light emitting characteristics similar to those of the active layer 54 having the profile shown in FIG. 6A. In the present embodiment, the first stress relieving layer 551 and the second stress relieving layer 552 can be a multiple layer structure, and each layer is made of a Group III nitride based material with different composition ratio.

Similarly, the band gap profiles of the first stress relieving layer 551 and the second stress relieving layer 552 in FIG. 11 are stepwise increasing. The only difference between the profile of FIG. 10 and the profile of FIG. 11 is that the profile of FIG. 10 is an equally stepwise graded profile, and the profile of FIG. 11 is not. However, the active layer 54 having an unequally stepwise graded profile still can have light emitting characteristics similar to those of the active layer 54 having the profile shown in FIG. 7A.

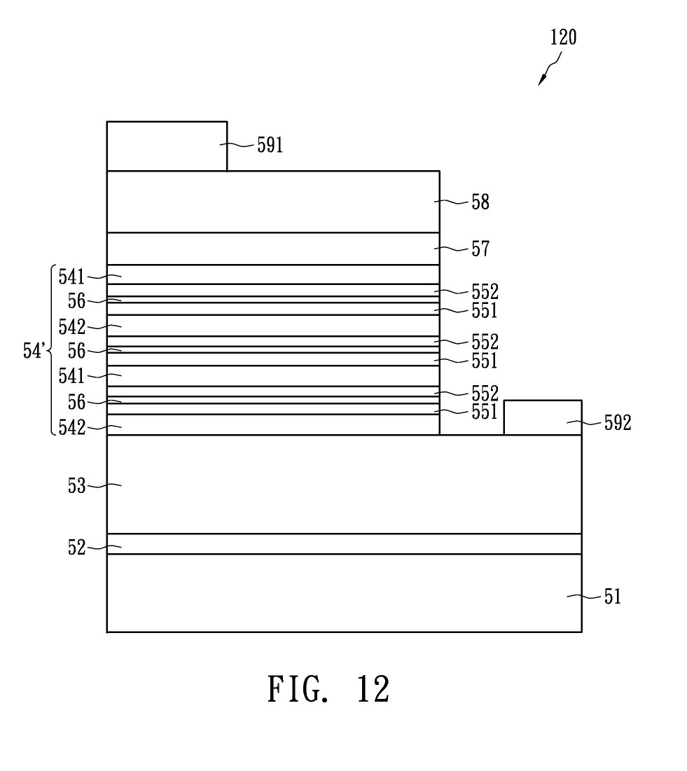

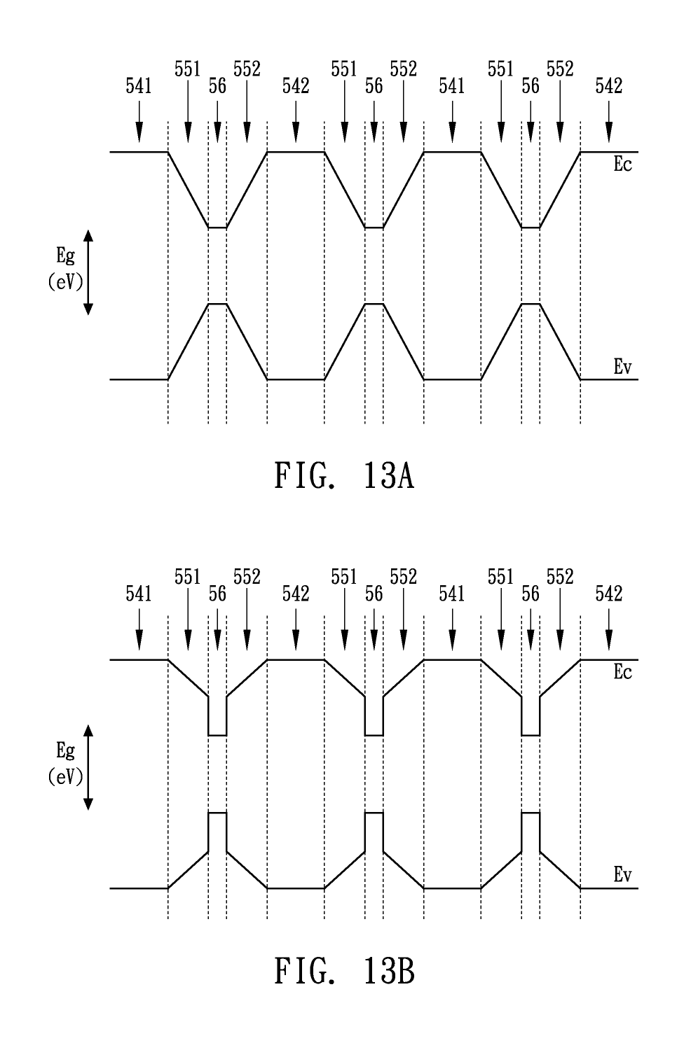

FIG. 12 is a schematic diagram of a light emitting device of Group III nitride based semiconductor according to the second embodiment of the present invention. Compared to FIG. 5, the light emitting device of Group III nitride based semiconductor 120 has a structure including a plurality of quantum well layers. The active layer 54′ comprises three quantum well layers 56, and each quantum well layer 56 is sandwiched by a first stress relieving layer 551 and a second stress relieving layer 552. The first barrier layer 541 and the second barrier layer 542 are separately disposed outside of the first stress relieving layer 551 and the second stress relieving layer 552 such that the first stress relieving layer 551 and the second stress relieving layer 552 are sandwiched therebetween. The multiple quantum well layer structure can include different stacked layers of embodiments, for example, from 2 stacked layers to 30 stacked layers (in the present embodiment, the number of staked layers is 3). However, the structures having 6 to 18 stacked layers are preferred.

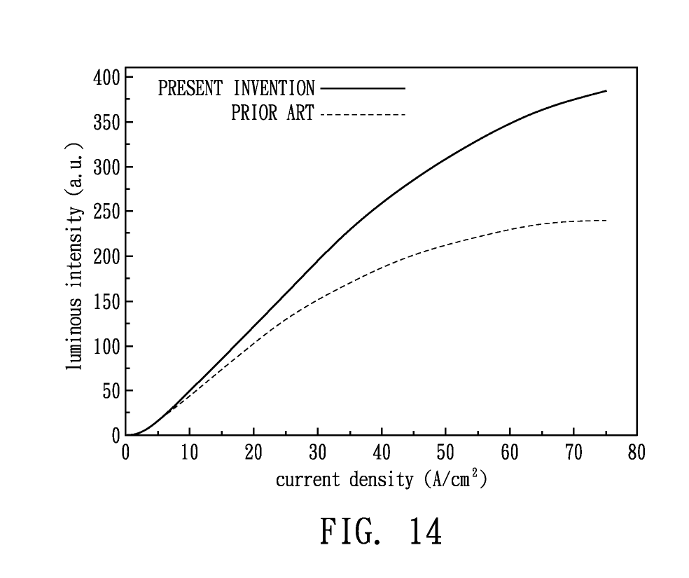

FIG. 13A and FIG. 13B are illustrative diagrams of the magnitudes of band gaps of the active layer with multiple quantum well layers according to another embodiment of the present invention. The structures of FIG. 13A and FIG. 13B are similar to the above-mentioned structure with a single quantum well layer, and the difference is that in the present embodiment, three quantum well layers are serially connected, and the detailed description of the present embodiment can refer to the description of the embodiments of FIG. 6A and FIG. 7A.

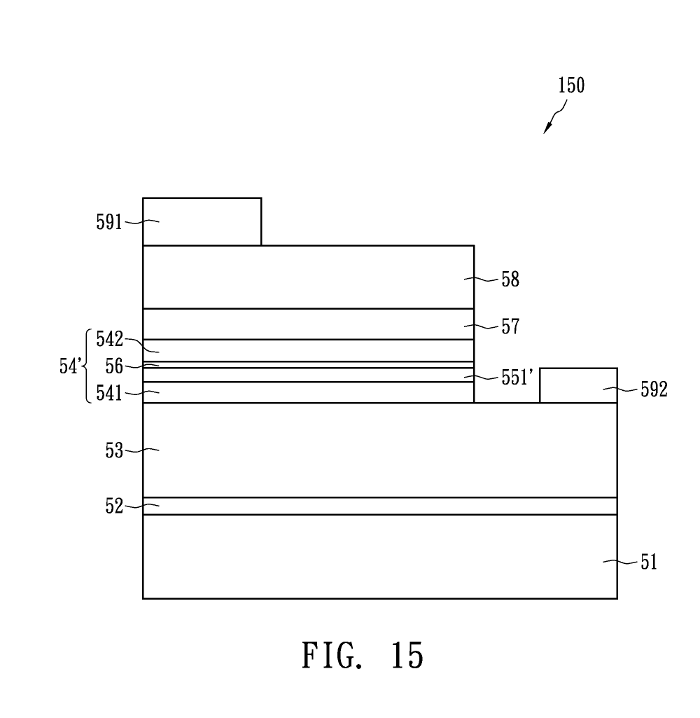

FIG. 14 shows curves of the output power of a light emitting device of Group III nitride based semiconductor according to one embodiment of the present invention and of a prior art device. Compared to the prior art light-emitting device, the light-emitting device of Group III nitride based semiconductor of the present invention can attain higher luminous intensity when the same current density is applied thereto. As a result, the light-emitting device of Group III nitride based semiconductor of the present invention has better optical efficiency.

FIG. 15 is a schematic diagram of a light emitting device of Group III nitride based semiconductor according to the third embodiment of the present invention. The light emitting device of Group III nitride based semiconductor 150 comprises a substrate 51, a buffer layer 52, an N-type semiconductor layer 53, an active layer 54″, a current block layer 57, and a P-type semiconductor layer 58. The active layer 54″ comprises at least one quantum well layer 56 and the first barrier layer 541 and the second barrier layer 542 formed to sandwich the quantum well layer 56 therebetween. In addition, the active layer 54″, moreover, comprises a stress relieving layer 551′, and the stress relieving layer 551′ is disposed between the first barrier layer 541 and the quantum well layer 56, or is disposed between the second barrier layer 541 and the quantum well layer 56. The N-type semiconductor layer 53 further comprises an N-type electrode layer 592, and the P-type semiconductor layer 58 further comprises a P-type electrode layer 591.

The difference between the present embodiment from the embodiment of FIG. 5 is that one stress relieving layer is formed between the quantum well layer and the barrier layer adjacent to the quantum well layer rather than two stress relieving layers separately formed between the quantum well layer and the barrier layers. However, the embodiment of FIG. 5, in which two stress relieving layers are disposed separately on both sides of the quantum well layer and are respectively sandwiched by the quantum well layer and the corresponding barrier layer, is preferred. Moreover, persons skilled in the art will understand from the above-mentioned embodiments that there can be one, two or more than two stress relieving layers, and the stress relieving layer(s) can be disposed on both sides or one side of the quantum well layer.

The above-described embodiments of the present invention are intended to be illustrative only. Numerous alternative embodiments may be devised by persons skilled in the art without departing from the scope of the following claims.

What is claimed is:

1. A light emitting device of Group III nitride based semiconductor, comprising:
a substrate;
an N-type semiconductor layer formed on the substrate;
an active layer formed on the N-type semiconductor layer, the active layer comprising at least one quantum well layer, at least two barrier layers sandwiching the quantum well layer therebetween and at least one stress relieving layer, wherein the stress relieving layer is interposed between the quantum well layer and one of the at least two barrier layers, and the composition of the stress relieving layer, made of Group III nitride based material, is graded along the direction from the quantum well layer to the barrier layers adjacent thereto; and
a P-type semiconductor layer formed on the quantum well layer.

2. The light emitting device of Group III nitride based semiconductor of claim 1, wherein the Group III nitride based material of the stress relieving layer is represented by the formula AlₓIn_{y}Ga_{1-x-y}N, wherein 0≦x<1, 0≦y<1 and x+y≦1.

3. The light emitting device of Group III nitride based semiconductor of claim 2, wherein the composition ratio among components, Al (aluminum), Ga (gallium), and In (indium), is graded along the direction from the quantum well layer to the barrier layers adjacent thereto.

4. The light emitting device of Group III nitride based semiconductor of claim 1, wherein the composition is monotonically and linearly graded or monotonically and non-linearly graded.

5. The light emitting device of Group III nitride based semiconductor of claim 1, wherein the composition is equally stepwise graded or is unequally stepwise graded.

6. The light emitting device of Group III nitride based semiconductor of claim 1, wherein the stress relieving layer comprises a multiple layer structure, and each layer is made of a Group III nitride based material with different composition ratio.

7. The light emitting device of Group III nitride based semiconductor of claim 1, wherein the stress relieving layer is a Group III nitride based semiconductor layer doped with N-type impurities or is an undoped Group III nitride based semiconductor layer.

8. The light emitting device of Group III nitride based semiconductor of claim 1, wherein the thickness of the stress relieving layer is greater than the thickness of the quantum well layer, but less than the thickness of the barrier layer.

9. The light emitting device of Group III nitride based semiconductor of claim 1, further comprising a buffer layer disposed between the substrate and the N-type semiconductor layer.

10. The light emitting device of Group III nitride based semiconductor of claim 1, further comprising a current block layer disposed between the active layer and the P-type semiconductor layer.

11. A light emitting device of Group III nitride based semiconductor, comprising:
a substrate;
an N-type semiconductor layer formed on the substrate;
an active layer formed on the N-type semiconductor layer, the active layer comprising:
at least one quantum well layer;
at least two barrier layers; and
at least one stress relieving layer interposed between the quantum well layer and one of the at least two barrier layers, wherein the stress relieving layer has a band gap energy greater than that of the quantum well layer; the stress relieving layer has a band gap energy smaller than that of the barrier layer adjacent thereto; and the stress relieving layer has a graded band gap along the direction from the quantum well layer to the barrier layers adjacent thereto; and
a P-type semiconductor layer formed on the quantum well layer.

12. The light emitting device of Group III nitride based semiconductor of claim 11, wherein the stress relieving layer is made of Group III nitride based material, and the Group III nitride based material is represented by the formula AlₓIn_{y}Ga_{1-x-y}N, wherein 0≦x<1, 0≦y<1 and x+y≦1.

13. The light emitting device of Group III nitride based semiconductor of claim 12, wherein the composition ratio among components, Al (aluminum), Ga (gallium), and In (indium), is graded along the direction from the quantum well layer to the barrier layers adjacent thereto.

14. The light emitting device of Group III nitride based semiconductor of claim 11, wherein the stress relieving layer has a monotonically and linearly graded band gap or a monotonically and non-linearly graded band gap.

15. The light emitting device of Group III nitride based semiconductor of claim 11, wherein the stress relieving layer has an equally or unequally stepwise graded band gap.

16. The light emitting device of Group III nitride based semiconductor of claim 11, wherein the stress relieving layer comprises a multiple layer structure, and each layer is made of a Group III nitride based material with different composition ratio.

17. The light emitting device of Group III nitride based semiconductor of claim 11, wherein the stress relieving layer is a Group III nitride based semiconductor layer doped with N-type impurities or is an undoped Group III nitride based semiconductor layer.

18. The light emitting device of Group III nitride based semiconductor of claim 11, wherein the thickness of the stress relieving layer is greater than the thickness of the quantum well layer, but less than the thickness of the barrier layer.

19. The light emitting device of Group III nitride based semiconductor of claim 11, further comprising a buffer layer disposed between the substrate and the N-type semiconductor layer.

20. The light emitting device of Group III nitride based semiconductor of claim 11, further comprising a current block layer disposed between the active layer and the P-type semiconductor layer.

21. A light emitting device of Group III nitride based semiconductor, comprising:
a substrate;
an N-type semiconductor layer formed on the substrate;
an active layer formed on the N-type semiconductor layer, the active layer comprising a quantum well layer, at least two barrier layers formed to sandwich the quantum well layer therebetween and at least two stress relieving layers, wherein the stress relieving layers are respectively interposed between the quantum well layer and the barrier layers, and the composition of the stress relieving layer, made of Group III nitride based material, is graded along the direction from the quantum well layer to the barrier layers adjacent thereto; and
a P-type semiconductor layer formed on the quantum well layer.

22. The light emitting device of Group III nitride based semiconductor of claim 21, wherein the Group III nitride based material of the stress relieving layer is represented by the formula AlₓIn_{y}Ga_{1-x-y}N, wherein 0≦x<1, 0≦y<1 and x+y≦1.

23. The light emitting device of Group III nitride based semiconductor of claim 22, wherein the composition ratio among components, Al (aluminum), Ga (gallium), and In (indium), is graded along the direction from the quantum well layer to the barrier layers adjacent thereto.

24. The light emitting device of Group III nitride based semiconductor of claim 21, wherein the composition is monotonically and linearly graded or monotonically and non-linearly graded.

25. The light emitting device of Group III nitride based semiconductor of claim 21, wherein the composition is equally stepwise graded or is unequally stepwise graded.

26. The light emitting device of Group III nitride based semiconductor of claim 21, wherein the stress relieving layer comprises a multiple layer structure, and each layer is made of a Group III nitride based material with different composition ratio.

27. The light emitting device of Group III nitride based semiconductor of claim 21, wherein the stress relieving layer is a Group III nitride based semiconductor layer doped with N-type impurities or is an undoped Group III nitride based semiconductor layer.

28. The light emitting device of Group III nitride based semiconductor of claim 21, wherein the thickness of the stress relieving layer is greater than the thickness of the quantum well layer, but less than the thickness of the barrier layer.

29. The light emitting device of Group III nitride based semiconductor of claim 21, further comprising a buffer layer disposed between the substrate and the N-type semiconductor layer.

30. The light emitting device of Group III nitride based semiconductor of claim 21, further comprising a current block layer disposed between the active layer and the P-type semiconductor layer.
